(19) United States
(12) Patent Application Publication
(10) Pub. No.: US 2026/0342044 A1
(43) Pub. Date: Oct. 29, 2026

(54) OSCILLATOR ARRANGEMENT AND METHOD

(71) Applicant: ams-OSRAM International GmbH, Regensburg (DE)

(72) Inventor: Hubert HALBRITTER, Dietfurt-Toeging (DE)

(73) Assignee: ams-OSRAM International GmbH, Regensburg (DE)

(21) Appl. No.: 19/122,161

(22) PCT Filed: Oct. 19, 2023
(86) PCT No.: PCT/EP2023/079166

§ 371 Date: Apr. 17, 2025

(30) Foreign Application Priority Data
Oct. 21, 2022 (DE) 10 2022 127 877.8

(51) Int. Cl. H01S 5/12; H01S 5/06; H01S 5/34

(52) U.S. Cl. CPC H01S 5/12; H01S 5/0601; H01S 5/34; H01S 2302/02

(57) ABSTRACT

The invention relates to an oscillator arrangement for generating THz radiation with an active laser layer structure based on a semiconductor material for emitting laser light of at least one wavelength, the main emission direction of which is substantially perpendicular to a main emission surface. A 2D grating structure which is arranged substantially parallel to the main emission surface, interacts with the active laser layer structure, such that the active laser layer structure is excited to form two laser modes of different frequency The oscillator arrangement further includes a mixer structure arranged in the emission direction, which is designed to form a difference signal from the two laser modes, and a downstream absorption element which is non-transparent for the two laser modes.

### CROSS-REFERENCE TO RELATED APPLICATIONS

The present application is a national stage entry from International Application No. PCT/EP 2023/079166, filed on Oct. 19, 2023, published as International Publication No. WO 2024/083995 A1 on Apr. 25, 2024, and claims the priority of the German application DE 10 2022 127 877.8 filed on Oct. 21, 2022, the disclosure of all of which are hereby incorporated by reference in their entireties.

### FIELD

The present invention relates to an oscillator circuit, in particular a THz oscillator, and a method for operating such an oscillator

### BACKGROUND

Modern telecommunications systems require ever higher base frequencies due to the increasing demands on bandwidth and data volume. For the sixth generation (6G) telecommunications standard, there is talk of using transmission frequencies that lie above the microwave range in the so-called THz range.

Microwave radio already exists, using directional radiation in the range up to approx. 90 GHz. Even higher base frequencies would allow a significantly higher bandwidth and therefore data volume. Various institutes and companies have therefore proposed frequency ranges above 300 GHz, which are assigned to the THz range. This ranges from 300 GHz to approx. 100 THz (in some definitions only up to approx. 30 THz) and therefore has wavelengths from approx. 1 mm to approx. 3 μm, i.e. up to the mid-infrared range of the spectrum.

In addition to telecommunications, however, other applications are also conceivable. For example, THz radiation can also be used for non-contact scanning, as electromagnetic radiation in this range can penetrate clothing and make objects underneath visible. Applications of this type are known as body scanners and are used in airports, for example, where only a detector that is sensitive to radiation in this range is used. A similar application is in materials testing, as many materials react to THE radiation in a characteristic way, or in biological or medical research.

One of the challenges for these applications is the generation of preferably narrow-band radiation in this range. Systems with lower output powers can be realized, but for higher powers laser arrangements are often used whose light is processed in a suitable way. For example, it is possible to combine and amplify the light of two lasers via an erbium-doped glass fiber connection. However, this setup is relatively large and the output power is still limited.

There is therefore a need for other solutions with which a higher output power can be achieved.

### SUMMARY OF THE INVENTION

This need is met by the objects of the independent patent claims. Further developments and embodiments of the proposed principle are given in the dependent claims.

The inventor proposes using a special new type of laser device to generate THz radiation and to combine this with other measures. The laser arrangement used is characterized by the fact that a 2D grating structure is used, which scatters the light linearly in the plane and orthogonally out of the plane. However, the orthogonal surface emission, similar to an out-of-plane VCSEL, offers several performance advantages for lasers, as the output power can be scaled with the emission area of the device with suitable heat dissipation.

The out-of-plane emission is enabled and stabilized by the 2D lattice structure (for example in the form of a photonic crystal), which also causes the feedback, among other things. A suitable selection of the structural elements of the grating structure as well as their shape and arrangement can excite the laser device to multi-mode emission. The threshold for the multi-mode emission can be set by the grating structure so that it can be ensured that both modes to be used also oscillate. A frequency or wavelength spacing can be set by the material of the laser arrangement itself. The two laser modes can be fed to a mixed structure, which in turn generates a differential signal and thus provides the desired radiation. The wavelength or also the frequency of the difference signal in the THz range is set by a suitable selection of the modes to be oscillated by means of the design of the laser device and the grating structure.

This creates an oscillator that, on the one hand, provides a defined frequency in the THz range with frequency stability and, on the other hand, delivers a high output power in the m-watt or even watt range. The area required for such a realization is significantly smaller than for conventional solutions. The amplitude of the output signal can be modulated by adjusting the current or changing the mixer structure.

In some aspects, the mixer structure can also serve as an antenna. In some other aspects, a separate antenna structure is provided that is configured to emit radiation in the defined frequency range. In some aspects, the antenna structure is coupled to the mixer structure or the material of the mixer structure such that the radiation in the mixer structure is guided to the antenna. Among other things, suitable waveguide structures can be provided for this purpose.

In one aspect, the oscillator arrangement, in particular in the form of a THz oscillator, comprises an active laser layer structure based on a semiconductor material. The laser layer structure is designed to emit laser light of at least one wavelength whose main radiation direction is essentially perpendicular to a main radiation surface of the layer structure.

A lattice structure, in particular a two-dimensional lattice structure, is operatively connected to the active laser layer structure. In this context, a two-dimensional lattice structure is understood to be a structure whose elements are essentially located in a plane spanned by two orthogonal spatial directions. This plane, and thus the lattice structure, is essentially parallel to the main surface. It interacts with the laser layer structure in such a way that the active layer in the laser layer structure is excited during operation to form two laser of different frequencies.

In other words, the laser layer structure interacts with the grating structure to generate two laser modes with slightly different frequencies. The two signals generated in this way are relatively narrowband and in some aspects polarized in the same direction. According to the proposed principle, a mixer structure arranged in the direction of radiation is also provided, which is designed to form a differential signal from the two laser modes.

The difference signal forms the THz radiation according to the invention and thus the output signal provided by the oscillator arrangement according to the invention.

Some aspects deal with the arrangement of the various elements, i.e. the lattice structure and the laser layer structure with each other. In some aspects, the lattice structure is made of a conductive material so that it also serves to conduct current to an active layer of the laser layer structure. In at least some aspects, it may be provided that the material of the lattice structure is different from the semiconductor material. This is expedient in order to be able to utilize differences in the various refractive indices in addition to shape, orientation and other parameters.

In some aspects, the grating structure interacting with the active laser layer structure is arranged on a side facing away from the main emitting surface. However, the grating structure, in particular in the form of a photonic structure, interacts with the active layer so that only laser light is excited and scattered perpendicular to the plane following the conditions of the band structure generated by the photonic structure. The arrangement of the photonic structure “below” the active layer may also have the advantage that the decoupling of the light from the laser layer structure can be separated from the mode shaping by the photonic structure, so that both aspects can be optimized separately. Alternatively, the grating structure interacting with the active laser layer structure can form at least part of the main emitting surface.

In both cases, in some embodiments, the grating structure cooperating with the active laser layer structure may be arranged between an active layer of the laser layer structure and a semiconductor layer for supplying the charge carriers. In other words, the laser layer structure and the grating structure are integrated in a common body or are also designed as a common body. In order to increase the interaction between the active layer of the laser layer structure and the grating structure, in some aspects the distance can be as small as possible and be in the range below 1 μm. In these cases, the grating structure is designed with conductive materials to ensure current transport.

In some aspects, the active laser layer structure comprises a quantum well structure or a multiple quantum well structure. This is spatially separated from the lattice structure interacting with the laser layer structure or the active layer (i.e. the quantum well or multiple quantum well structure) by an electrically conductive blocking layer that prevents diffusion of impurities, in particular dopant atoms. The blocking layer is arranged adjacent to the quantum well structure or a multiple quantum well structure.

Some aspects deal with the shape and design of the lattice structure. For example, the lattice structure can comprise a quantized symmetry, i.e. a rotational or translational symmetry that is not continuous but only has defined values. In the case of rotational symmetry, for example, this would be fulfilled by means of a structural element whose rotational symmetry is limited to discrete values, for example to one of the values 30°, 45°, 60°, 90°, 180° and 360°. In the case of translational symmetry, the periodicity may not be repeated after every structure in one spatial direction, but possibly only after every second or another value. In this context, the lattice structure can also comprise a superlattice, so that the structure can thus form Several symmetries.

In another aspect, the lattice structure comprises a first periodically repeating structural element and a second periodically repeating structural element. Both structural elements can be independent of each other and the periodicity can also differ. It is therefore possible that not only a periodicity of the form ABABAB . . . can occur (with A and B corresponding to the respective structural elements), but also other periodicities, for example ABBABBABBA . . . or also ABABAABBAABAA-BAABBAABA . . . . Other structural elements with other periodicities are also conceivable, so that superlattices can also be formed. The shape, size and design of the structural elements can vary. For example, one structural element can be in the form of a semi-pyramid, the other in the form of a full pyramid or in another form. Alternating structures are also possible, which, for example, show a triangle or a square or polygons in general when viewed from above. Other structural elements are cylinders, which can be elliptical or round in shape when viewed from above.

In some aspects, it is possible that the structural element comprises a first periodicity in a first spatial direction and a second periodicity in a second spatial direction independent thereof. In this case, the first periodicity and the second periodicity are different from each other. Different periodicities in the different spatial directions are also possible for different structural elements.

The lattice can thus comprise structural elements of different shapes or designs, which can also have different periodicities in the different spatial directions. The lattice can also comprise a structural element which, due to its shape but uniform periodicity, produces the desired dual modes in both spatial directions. Likewise, depending on the desired design, combinations of the various above-mentioned parameters of material, shape, size, spatial direction, periodicity and symmetry are also possible.

In some further aspects, the oscillator arrangement further comprises an optical element arranged between the main emitting surface and the mixer structure. The optical element is configured to direct the light emitted from the active laser layer structure along the main emitting direction onto the mixer structure. It can be part of the active laser layer structure, i.e. embedded in its material or arranged on the main emitting surface. In some aspects, the optical element is integrated such that it forms the main emitting surface of the active laser layer structure.

In a further embodiment, the mixer structure comprises an absorption element downstream in the main radiation direction, which is essentially non-transparent for the two laser modes of different frequencies. The mixer structure may comprise a surface-active element. In lower frequency ranges, the mixer structure is formed by a non-linear element, for example a diode. A non-linear element made of or comprising a semiconductor material is also required to generate radiation in the THz range. This can be based on Ga, for example GaAs.

The absorption element, on the other hand, comprises a band gap that leads to the absorption of light from both laser modes. A suitable material for this would be Si, which is opaque to light in the near and mid-infrared at wavelengths in the range from 900 nm to 1000 nm, but allows the generated difference signal to pass through. The absorption element should comprise a different semiconductor material to the mixer structure.

In some aspects, the mixer structure is configured to directionally output the difference signal, in particular along a spatial direction or two opposite spatial directions. In some embodiments, a wavelength of the two laser modes lies in an infrared part of a spectrum, in particular above 900 nm and in particular above 950 nm. This results in a wavelength of the difference signal in the range from 1 mm to 3μm, in particular in the range from 1 mm to 0.1 mm.

A further aspect concerns a method for operating an oscillator arrangement according to the proposed principle. A current is modulated to generate laser light of the two laser modes. In this way, amplitude modulation of the generated THz radiation can be effected. However, it is at least possible in this way to regulate the output power in a certain range and thus adapt it to the desired application.

In the same way, the mixer structure can also be changed in its mixing efficiency or in other ways, so that the amplitude of the differential signal can also be changed here.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a first embodiment of a THz oscillator based on a PCSEL according to some aspects of the proposed principle;

FIG. 2 shows a second version of a THz oscillator based on a PCSEL according to some aspects of the proposed principle;

FIG. 3 shows a third embodiment of a THz oscillator based on a PCSEL according to some aspects of the proposed principle;

FIG. 4 is a frequency diagram showing a frequency of the difference signal from the frequencies of the dual modes according to some aspects of the proposed principle;

FIG. 5 is an embodiment of a laser layer structure for a THz oscillator based on a PCSEL according to some aspects of the proposed principle;

FIGS. 6A to 6C are plan views of various grating structures as applicable to a PCSEL for a THz oscillator according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects comprise a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

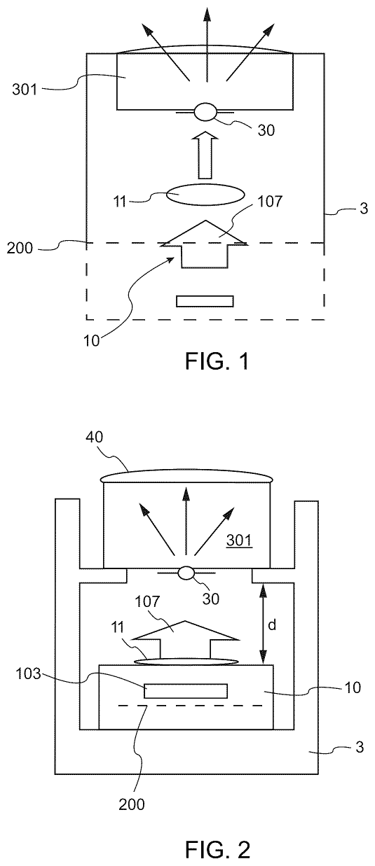

FIG. 1 shows a basic representation of a first version of a THz oscillator based on the proposed principle. The THz oscillator is installed in a housing 3 so that a space-saving design is possible. Although the oscillator shown here is formed from several separate assemblies, it is possible to integrate these into a common body, for example into a semiconductor body. As will be explained, this includes integration of the laser layer structure with the grating structure, but also further integration with optical elements or even with the mixer structure 30, which is also necessary.

The oscillator shown in FIG. 1 comprises a laser layer structure 10 based on a semiconductor material in its housing 3. The laser layer structure 10 is designed as a so-called PCSEL and integrates a grating structure with an active laser material in a common semiconductor body. The term PCSEL stands for photonic crystal surface emitting laser, i.e. for a surface-emitting laser with a photonic crystal structure.

PCSEL elements use a two-dimensional grating structure that scatters the light generated in the active layer in a characteristic and adjustable manner. In particular, the scattering is both linear in the plane and orthogonal to it, whereby the orthogonal scattering is utilized as it can be easily integrated and further processed. Out-of-plane emission is enabled and stabilized by the 2D lattice structure (photonic crystal), which creates the feedback. According to the proposed principle, a special design of the lattice structure ensures that the active layer of the laser layer structure oscillates not only on one mode, but on two different ones, which, however, show an energetically close operation threshold due to the underlying lattice structure. This threshold is given, among other things, by the FSR (free spectral range), which in turn depends on the virtual band structure and the eigenvalues of the underlying grating structure

It has been shown that grating structures comprising only a broken rotational symmetry (i.e. a rotational symmetry with only a few values, e.g. 180° or 360°), for example, lead to a band structure with low deployment thresholds due to their shape and thus lead to the generation of several oscillating modes in laser operation. Due to the scalability of the grating structure, can be realized on large laser layer structures with sufficient heat dissipation and thus achieve high output powers.

The feedback of the grating structure in the plane of such composite laser layer structures is two-dimensional, which enables coherently coupled arrays. In this way, the light can be focused more easily and very high luminance levels of dual modes can be achieved.

In the present embodiment example, the laser layer structure 10 with its active zone 103 is embedded in a semiconductor body. The lattice structure 200 in the form of a photonic crystal is also located on its surface, so that the emission area of the laser layer structure 10 is formed by the photonic structure. The emission of light with the two modes is essentially perpendicular to the emission surface. There is also a high level of collimation due to the lattice structure 200. Connected to the housing 3 in the beam path is an optical system 11, which directs the emitted laser light onto a mixer structure 30.

The mixer structure 30 is a non-linear element that interacts with the light of the two optical modes. The properties of the element generate a differential signal, i.e. a radiation with a differential frequency from the frequencies of the two modes. The mixer structure 30 can an optical mixer, for example in the form a PLC, a photodiode, a photoconductor or the like. Optical feed lines, for example glass fibers, are provided for this purpose, which couple the light from the laser layer structure and transmit it to the mixer structure 30. The mixer structure is again designed so that the differential signal emitted comprises a preferred direction, for example along the beam direction, as this simplifies further processing. In an alternative embodiment, the mixing frequency in the THz range is emitted via a further antenna which is coupled to the mixer structure 30.

In this context, FIG. 4 shows a frequency diagram with the two modes lying quite close to each other in frequency space with the frequencies f1 and f2. The distance can be adjusted by means of the grating structure, whereby it should be ensured that the onset thresholds for oscillation are also quite close to each other. This ensures that the amplitudes of the two laser modes are approximately the same, which is advantageous for subsequent mixing.

The optical mixer 30 is a non-linear element. This results in a mixed light, i.e. a difference or sum of the respective frequencies, when light with several frequencies is supplied. A frequency multiplication can also occur at very high intensities. In general, this results in a difference frequency: f_{D}=f₂−f₁, where f₂ is the frequency of the higher-energy light. The sum frequency f₂+f1 also occurs as well as other frequencies (f₂−f₁)/2, 3/2*(f₂−f₁) etc. However, these signals can be suppressed by suitable designs or circuitry.

At a wavelength of the two laser modes in an infrared part of the spectrum, in particular above 900 nm and in particular above 950 nm, a difference signal is generated in this way, the wavelength of which is again in the range from 1 mm to 3μm, in particular in the range from 1 mm to 0.1 mm. The corresponding frequency would then be 300 GHz to approx. 30 THz.

Referring back to the design shown in FIG. 1, an absorption element 300 is arranged in the beam path behind the mixer structure 30. This is transparent for the differential signal with the frequency in the THz range. On the other hand, the absorption element 300 is not transparent for the light generated by the laser layer structure 10. In particular, the element 300 is absorbent for light in the visible and near infrared spectrum in the range above 800 nm. One such material would be silicon, for example, which only needs to be a few μm thick. The absorption element 300 is also designed with sufficient thermal conductivity to ensure heat transfer of the absorbed light. Furthermore, this absorption element may also comprise waveguiding properties for the generated THz radiation. This allows the mixer structure to be connected to a antenna via the absorption material so that the antenna radiates the generated radiation in a suitable manner.

An absorption element 300 in the beam path is useful in order to prevent any unconverted light from one of the two modes from reaching an observer's eye or otherwise interacting with objects in the direction of radiation. On the other hand, the absorbing element 300 should also be absorbing. Although a reflective element is also conceivable, there is a risk here that reflected light can return to the laser layer structure and/or the mixer structure and lead to destructive interference or other detrimental effects. If this can be ruled out, a reflective element may even be suitable for placing downstream of the mixer in the beam path, as light reflected back into the mixer increases the conversion efficiency.

FIG. 2 shows a second embodiment of a THz oscillator based on the proposed principle. This is also integrated in a housing 3 and has an exit window on one side in which collimation optics 40 are arranged for the THz radiation shown. A collimation or focusing optic 11 is placed on the emission surface of the laser layer structure 10. This is slightly spaced from the mixer structure 30 by a distance d, whereby this is also attached to the housing 3. The distance is appropriate in order to ensure sufficient thermal decoupling between these two main elements.

In this embodiment, the grating structure, i. e. the photonic structure, which is designed to generate the dual modes, is arranged in the laser layer structure on the side facing away from the emission side. In other words, the grating structure 200 is no longer located in the beam path, but behind or below the active layer 102 for generating light, as viewed from the emission surface. It is possible to realize the photonic structure in the laser layer structure 20 close to the active layer, i.e. only a few 10 nm or 100 nm away from it. In this way, the grating structure 200 interacts with the active layer 103 and leads to the above-mentioned coupling. Likewise, the emission surface can also be optimized in this way, so that an outcoupling of the generated laser light can be optimized independently of the shape or structure of the photonic layer 103.

Downstream of the mixer structure 30 in the beam path is an absorption element 301 and the aforementioned collimation optics. In this embodiment example, the mixer structure 30 is integrated into a semiconductor body, whereby this also forms part of the absorption element 301. For example, this is formed together with the mixer structure 30 in a III/V semiconductor material. Suitable materials would include InP, (LT) GaAs (at 780 nm), GaN, SiGe, LTG InAlAs/InGaAs (at 1500 nm) or Sb. In addition, Si is also particularly suitable for the absorption element, as it has a strong absorbing effect for light in the infrared part of the spectrum, but is transparent for THz radiation. This prevents light that is not converted by the mixer element 30 from being collimated by the downstream optics 40 or leaving the oscillator housing 3.

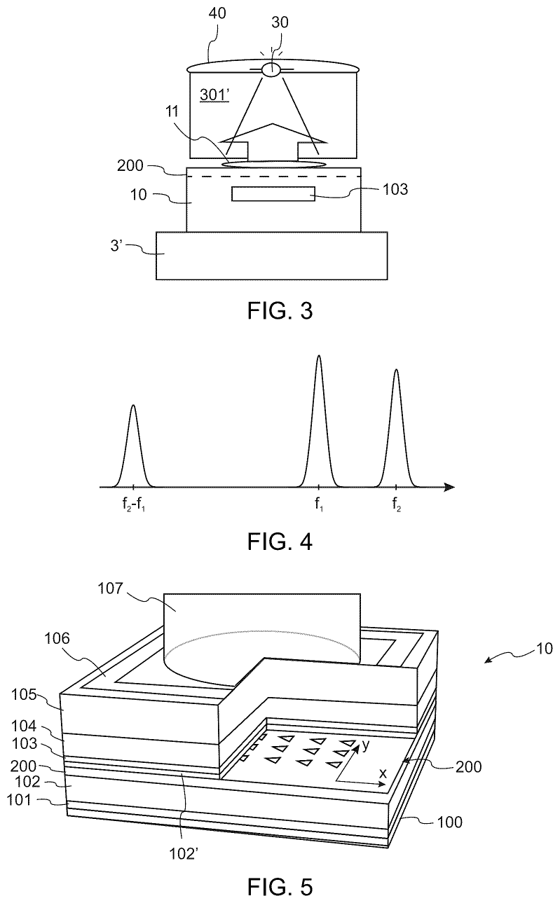

In the embodiment example shown in FIG. 3, a further miniaturization is carried out. In this embodiment, the laser layer structure 10 and an optical system arranged on the emission surface are arranged directly on a light guiding element 301′, which on the one hand guides the light emitted by the laser layer structure 10 onto the mixer structure and on the other hand prevents feedback into the laser layer structure 10. The grating structure is arranged in the material of the laser layer structure above the active layer 103 but below the emission surface.

The mixer structure generates a differential signal from the coupled light with the two modes, which is collimated and emitted by the optics 40. In this embodiment, the elements 301′ and 30 as well as 40 are arranged directly on the material of the laser layer structure 10. However, this conducts the heat well to a heat sink 3′ connected to the laser layer structure.

FIG. 5 is an example of a surface-emitting laser in a semiconductor material, in which the grating structure is also integrated. The grating structure must be conductive in order to ensure current transport into the active layer. In the present embodiment example, the laser layer structure 10 comprises a bottom-side p-contact 100 made of a conductive material, for example a metal. The contact 100 can be connected to the housing or can itself form part of the housing (not shown here).

Following this, the layer structure 10 comprises a contact layer 101, which is also p-doped, in this case made of doped GaAs. The doped GaAs distributes the current impressed via the contact 100 over the surface. This is followed by a separating layer (cladding) 102 on which the grid structure 200 is applied. The grid structure is made of the same material system as the layers already mentioned, i.e. in this case GaAs or AlGaAs, which can also be doped in order to have the lowest possible sheet resistance. The lattice structure is now separated from the active layer 103 by an undoped blocking layer 102′. Although this is conductive, it prevents the diffusion of dopant atoms into or out of the active layer. This prevents or reduces degradation of the active layer 103 over time.

The active layer 103 comprises a quantum well or a multiple quantum well structure. For example, GaAs/AlGaAs layers can be used for this purpose, whereby these are also doped and thus form a sequence of barrier and well layers. Alternatively, other ternary material systems can also be used to form such a multiple quantum well structure. For example, the Al in the AlGaAs material can be partially or completely replaced by In. This is useful because the wavelength of the emitted light is essentially dependent on the ratios in the multiple quantum well structure. By using In and Al in different concentrations, the wavelength for light generation can be adjusted (both wavelength and width) so that, in interaction with the photonic structure 200, two modes oscillate that are shifted by a freequence amount, the difference between which produces the desired THz radiation.

An n-doped injection layer 104, for example of n-doped AlGaAs, is applied to the multiple quantum well structure 103 and a further layer 105, which also consists of a semiconductor material, is applied to this. It is possible to reverse the manufacturing sequence so that the layer 105 forms a doped growth substrate on which the subsequent layers and, in particular, the lattice structure 200 are deposited epitaxially

The surface of the layer 105 also forms the main emission surface of the laser layer structure 10 for the laser light 107. A metallic contact 106 in the form of a window is also arranged on the surface of the layer 105 for current supply. The contact 106 surrounds the emission area.

In this example, the photonic structure is thus arranged below the active layer, i.e. on the side facing away from the emission area on the surface. However, it can also be provided between the emission area and the active layer. It is also possible to provide it on the surface of the layer 105. For this purpose, after the individual layers have been produced, the surface of the layer 105 is exposed and the photonic layer 200 is produced on it as a lattice structure according to the proposed principle. This can be done additively, i.e. by creating the structure by means of a patterned deposition process, or subtractively, i.e. by etching the structures. In practice, combinations of etching and deposition processes are also possible.

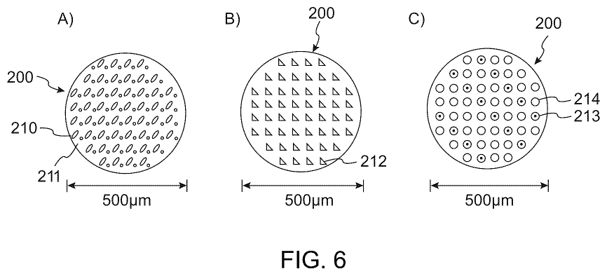

FIGS. 6A to 6C show various embodiments of a photonic structure 200 in plan view, such as can be used to form dual modes in a surface-emitting laser. The structures each have one or more structural elements 210 to 214, which in turn can be arranged periodically. The size of these structures is in the range of a few μm, for example between 10 μm and 35 μm. It is possible for the individual structural elements in a lattice structure to comprise a different periodicity, as is shown, for example, for the structural elements 213 and 214 in FIG. 6C. Neighboring elements 213 have a greater distance from each other than neighboring elements 214.

In addition, the symmetry can also differ in the respective spatial directions, i.e. there may be a translation symmetry in the x-direction, for example, which differs from a translation symmetry in the y-direction. The respective periodicities can be complex and adapted to the respective application.

In addition, the structural elements themselves are designed differently, for example in FIGS. 6A and 6C. The design of the individual elements is such that there is no continuous rotational symmetry, but rather, if present, it can only assume a few discrete values. For example, FIG. 6A shows a photonic structure 200 with two structural elements 210 and 211. While element 211 is rotationally symmetrical as a circular or cylindrical structure, this is broken for element 211 in such a way that a rotation around the central axis through 180° and 360° only leads to the same element again. Element 211 has the shape of an ellipse when viewed from above.

If both elements 210 and 211 are now considered together as a cell, the rotational symmetry is reduced even further. Only a 360° rotation returns to the original element. The same applies to the design in FIG. 6B. Here, the structural elements 212 are designed as semi-pyramids, so that they form an isosceles triangle when viewed from above. Here too, the rotational symmetry is broken, i.e. the structural elements only map onto themselves when rotated through 360°

The designs shown here can be combined in various ways. The underlying principle of forming THz radiation by mixing light generated by a PCSEL as a dual mode laser remains unaffected. The THz oscillator according to the proposed principle can also be further developed into an amplitude modulation. The laser current can be varied for this purpose. This changes the amplitudes of the generated light and thus achieves amplitude modulation of the generated THz radiation.

As an alternative, it is also possible to vary the conversion efficiency of the mixer structure, i.e. its efficiency with regard to the conversion and formation of the difference signal, so that the intensity of the difference signal and thus the amplitude of the THz radiation can be varied. However, the first solution is preferred because of its greater conversion efficiency, since, in contrast to the second solution, it is not the efficiency of the conversion into THE radiation as such that is modulated, but only the output power of the laser light.

The proposed solution is a THz oscillator that is particularly easy to scale in size and thus in output power. The proposed solution can be realized in a space-saving manner. With good heat dissipation, a high output power in the range from mW to several W can be achieved.

1. An oscillator arrangement, in particular THz oscillator, comprising:
an active laser layer structure based on a semiconductor material for emitting laser light of at least one wavelength whose main radiation direction is substantially perpendicular to a main radiation surface;
a grating structure cooperating with the active laser layer structure in particular 2D grating structure, which is arranged substantially parallel to the main surface and is designed in such a way that the active laser layer structure is excited to form two laser modes of different frequency
a mixer structure arranged in the direction of radiation, which is designed to form a difference signal from the two laser modes with a frequency from the difference between the two laser modes; and
an absorption element arranged downstream of the mixer structure as seen in the main radiation direction, in particular comprising silicon, which is substantially non-transparent for the two laser modes of different frequency.

2. The oscillator arrangement according to claim 1, wherein the grating structure cooperating with the active laser layer structure is arranged on a side facing away from the main radiating surface; or in which the grating structure interacting with the active laser layer structure forms at least part of the main radiation surface.

3. The oscillator arrangement according to claim wherein the grating structure cooperating with the active laser layer structure is arranged between an active layer of the laser layer structure and a semiconductor layer for supplying the charge carriers.

4. The oscillator arrangement according to claim 1, in which the active laser layer structure comprises a quantum well structure or a multiple quantum well structure, and the lattice structure cooperating with the active laser layer structure is arranged adjacent to the quantum well structure or a multiple quantum well structure, separated by an electrically conductive blocking layer which, however, prevents diffusion of foreign atoms, in particular dopant atoms

5. The oscillator arrangement according to claim 1, wherein the lattice structure comprises a periodically repeating structural element whose rotational symmetry is in particular limited to one of 30°, 45°, 60°, 90°, 180° and 360°.

6. The oscillator arrangement according to claim 1, wherein the lattice structure comprises a first periodically repeating structural element and a second periodically repeating structural element whose size and/or shape is different from the first structural element.

7. The oscillator arrangement according to claim 5, wherein a periodicity of the structural element in a first spatial direction is different from a periodicity in a second spatial direction.

8. The oscillator arrangement according to claim 1, further comprising an optical element which is arranged between the main radiation surface and the mixer structure and is designed to direct the light emitted by the active laser layer structure along the main radiation direction onto the mixer structure.

9. The oscillator arrangement according to claim 1, wherein the absorption element comprises a semiconductor material, in particular silicon, different from the mixer structure

10. The oscillator arrangement according to claim 1, wherein the mixer structure is designed for a directional output of the difference signal, in particular along one spatial direction or two opposite spatial directions.

11. The oscillator arrangement according to claim 1s, in which one wavelength of the two laser modes lies in an infrared part of a spectrum, in particular above 750 nm, in particular above 900 nm and in particular above 950 nm; and/or in which a wavelength of the difference signal is in the range from 1 mm to 3 μm, in particular in the range from 1 mm to 0.1 mm.

12. The oscillator arrangement according to claim 1, further comprising an antenna structure coupled to the mixer structure for forwarding and transmitting the generated radiation.

13. A method of operating an oscillator arrangement according to claim 1,
in which a current is modulated to generate laser light of the two laser modes; or
in which the mixing efficiency of the mixer structure is changed to generate an amplitude-modulated differential signal.
